(19) United States
(12) Patent Application Publication
(10) Pub. No.: US 2026/0176517 A1
(43) Pub. Date: Jun. 25, 2026

(54) HEAT PUMP WATER HEATER WITH PHASE CHANGE MATERIAL HEAT EXCHANGER

(71) Applicants: Alliance for Energy Innovation, LLC, Golden, CO (US); Colorado School of Mines, Golden, CO (US)

(72) Inventors: Adewale ODUKOMAIYA, Denver, CO (US); Paulo Cesar TABARES VELASCO, Littleton, CO (US); Jason David WOODS, Boulder, CO (US); Bethany Fisher SPARN, Boulder, CO (US); Jeffrey Brad MAGUIRE, Boulder, CO (US); Thomas Benjamin FREEMAN, Denver, CO (US); Kyle Edward O’Neil FOSTER, Denver, CO (US)

(21) Appl. No.: 19/409,975

(22) Filed: Dec. 5, 2025

Related U.S. Application Data
(60) Provisional application No. 63/728,329, filed on Dec. 5, 2024.
(60) Provisional application No. 63/874,769, filed on Sep. 3, 2025.

(51) Int. Cl. C09K 5/06; F24H 4/04; F24H 15/225; H10N 70/20

(52) U.S. Cl. CPC C09K 5/063; F24H 4/04; F24H 15/225; H10N 70/231

(57) ABSTRACT

A heat pump hot water heater (HPWH) integrated with a phase change material (PCM) thermal energy storage (TES) system for improving energy efficiency and/or allowing for a smaller space profile for the hot water heater. The PCM may allow for hot water to be provided without use of electrical energy and/or for a greater volume of hot water to be provided than the volume of the HPWH tank itself. The PCM may be submerged in the water or located in the corners around the cylindrical heat pump water heater.

### CROSS-REFERENCE TO RELATED APPLICATIONS

This application claims priority from U.S. Provisional Patent Application No. 63/728,329 filed on Dec. 5, 2024, and U.S. Provisional Patent Application No. 63/874,769 filed on Sep. 3, 2025, the contents of which are incorporated herein by reference in their entirety.

### CONTRACTUAL ORIGIN

This invention was made with United States government support under Contract No. DE-AC36-08GO28308 awarded by the U.S. Department of Energy. The United States government has certain rights in this invention.

### BACKGROUND

Electrification of water heaters is a key step to transforming the U.S. into a carbon-neutral country. heat pump water heaters (HPWHs) are a sustainable all-electric high-efficiency alternative to traditional gas-fired and electric resistance water heaters with similar thermal performance. HPWHs combine a vapor compression system with a tank of water. The evaporator pulls heat from the surrounding air and moves that heat into the tank via the condenser. This condenser is typically wrapped around the tank in aluminum microchannel heat exchangers. Refrigerant condenser in these heat exchangers conduct heat through the tank and into the water.

HPWHs are currently not a viable alternative to traditional gas-fired and electric resistance water heaters for several reasons. Primarily, to maintain and/or retrofit a HPWH may require costly panel upgrades, and a HPWH may be larger than standard gas and electric water heaters because of the additional compressor and evaporator heat exchanger, limiting the locations in a home where it may be placed. Thus, there remains a need for HPWH a viable alternative to traditional hot water heaters.

### SUMMARY

An aspect of the present disclosure is a method including charging a phase change material using a condenser coil, heating a water using the condenser coil, storing the water in a tank, and discharging the phase change material using the water, in which the condenser coil is a part of a heat pump water heater, the phase change material has a transition temperature, the charging occurs when the condenser coil is at a temperature higher than the transition temperature, and the discharging occurs when the water is at a temperature less than the transition temperature. In some embodiments, the heating comprises operating the heat pump hot water heater. In some embodiments, the transition temperature is approximately 40° C. In some embodiments, the phase change material is located inside the tank, and the phase change material is contained in a matrix. In some embodiments, the discharging includes transferring a heat from the phase change material to the water, resulting in the water increasing in temperature. In some embodiments, the phase change material is located outside of the tank, a piping is configured to direct the water from the tank to an end use, and the piping is positioned within the phase change material. In some embodiments, the discharging occurs when the water in the piping is at a temperature less than the transition temperature. In some embodiments, the phase change material is located outside of the tank, a piping is configured to direct the water to the tank, and the piping is positioned within the phase change material. In some embodiments, the discharging occurs prior to the heating. In some embodiments, the discharging occurs when the water in the piping is at a temperature less than the transition temperature.

An aspect of the present disclosure is a device including a heat pump comprising a condenser coil, a tank comprising an interior, and a phase change material in thermal communication with the condenser coil and having a transition temperature, in which the condenser coil is configured to heat a water, the condenser coil is configured to heat the phase change material when the phase change material is at a temperature less than the transition temperature, and the phase change material is configured to heat the water when the water is at a temperature less than the transition temperature. In some embodiments, the transition temperature is approximately 40° C. In some embodiments, the phase change material is located in the interior, the phase change material is contained in a matrix, and the phase change material is configured to heat the water when the water in the interior is at a temperature less than the transition temperature. In some embodiments, the phase change material comprises at least one of polyphenyl sulfone (PPSU), polypropylene (PP), polyvinylidene fluoride (PVD), or acrylonitrile-styrene-acrylate (ASA). In some embodiments, the phase change material is configured to heat the water when the water in the interior is at a temperature less than the transition temperature. In some embodiments, the phase change material is located outside of the tank, and the phase change material comprises a salt hydrate. In some embodiments, the phase change material is located outside of the tank, a piping is configured to direct the water from the tank to the end use, and the piping is positioned within the phase change material. In some embodiments, the phase change material is configured to heat the water when the water in the piping is at a temperature less than the transition temperature. In some embodiments, the phase change material is located outside of the tank, a piping is configured to direct the water to the tank, and the piping is positioned within the phase change material. In some embodiments, the phase change material is configured to transfer heat to the water before the water enters the interior, and the phase change material is configured to heat the water when the water when the water in the piping is at a temperature less than the transition temperature.

### BRIEF DESCRIPTION OF THE DRAWINGS

Some embodiments of the present disclosure are illustrated in the referenced figures of the drawings. It is intended that the embodiments and figures disclosed herein are to be considered illustrative rather than limiting.

FIG. 1 illustrates a first embodiment of a heat pump hot water heater (HPWH) including a phase change material (PCM) heat exchanger, according to some aspects of the present disclosure.

FIG. 2 illustrates materials and manufacturing approaches for the creation of microencapsulated PCMs/polymer scaffolds using 3D printing (bottom right) and molding (top right) for use in one embodiment of a HPWH including a PCM heat exchanger, according to some aspects of the present disclosure.

FIG. 3 illustrates stackable substantially isothermal nodes for a stratified model of a first embodiment of a HPWH including a PCM heat exchanger, according to some aspects of the present disclosure.

FIG. 4 illustrates thermodynamic calculation results for a first embodiment of a HPWH including a PCM heat exchanger, according to some aspects of the present disclosure.

FIG. 5A illustrates a top view of a second embodiment of a PCM-integrated HPWH having PCM integrated in two external corners; FIG. 5B illustrates a top view of a second embodiment of a PCM-integrated HPWH having PCM integrated into two external corners and a side, according to some aspects of the present disclosure.

FIG. 6A illustrates a top view of a second embodiment of a PCM-integrated HPWH having PCM surrounding the water tank; FIG. 6B illustrates a top view of a second embodiment of a PCM-integrated HPWH having PCM surrounding the water tank and integrated into two external corners and a side, according to some aspects of the present disclosure.

FIG. 7A illustrates a close up top view of a second embodiment of a PCM-integrated heat pump water heater during charging and FIG. 7B illustrates a second embodiment of a close up top view of a PCM-integrated heat pump water heater during discharging, according to some aspects of the present disclosure.

REFERENCE NUMERALS

| | |
|---|---|
| 100 | heat pump hot water heater (HPWH) |
| 105 | phase change material (PCM) |
| 110 | water inlet |
| 115 | water outlet |
| 120 | insulation |
| 125 | pipes |
| 130 | heat |
| 135 | tank interior |
| 140 | condenser heat exchanger coils |
| 145 | node |

### DETAILED DESCRIPTION

The embodiments described herein should not necessarily be construed as limited to addressing any of the particular problems or deficiencies discussed herein. References in the specification to “one embodiment”, “an embodiment”, “an example embodiment”, “some embodiments”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

As used herein the term “substantially” is used to indicate that exact values are not necessarily attainable. By way of example, one of ordinary skill in the art will understand that in some chemical reactions 100% conversion of a reactant is possible, yet unlikely. Most of a reactant may be converted to a product and conversion of the reactant may asymptotically approach 100% conversion. So, although from a practical perspective 100% of the reactant is converted, from a technical perspective, a small and sometimes difficult to define amount remains. For this example of a chemical reactant, that amount may be relatively easily defined by the detection limits of the instrument used to test for it. However, in many cases, this amount may not be easily defined, hence the use of the term “substantially”. In some embodiments of the present invention, the term “substantially” is defined as approaching a specific numeric value or target to within 20%, 15%, 10%, 5%, or within 1% of the value or target. In further embodiments of the present invention, the term “substantially” is defined as approaching a specific numeric value or target to within 1%, 0.9%, 0.8%, 0.7%, 0.6%, 0.5%, 0.4%, 0.3%, 0.2%, or 0.1% of the value or target.

As used herein, the term “about” is used to indicate that exact values are not necessarily attainable. Therefore, the term “about” is used to indicate this uncertainty limit. In some embodiments of the present invention, the term “about” is used to indicate an uncertainty limit of less than or equal to ±20%, ±15%, ±10%, ±5%, or ±1% of a specific numeric value or target. In some embodiments of the present invention, the term “about” is used to indicate an uncertainty limit of less than or equal to ±1%, ±0.9%, ±0.8%, ±0.7%, ±0.6%, ±0.5%, ±0.4%, ±0.3%, ±0.2%, or ±0.1% of a specific numeric value or target.

As used herein, the term “phase change material” (PCM) refers to a substance that can absorb and release energy in the form of latent heat when it changes from one physical state to another (i.e., between a solid and a liquid state) at a certain temperature. A PCM may be organic or inorganic. Exemplary PCMs may include hydrated salts, paraffin wax, and/or metal alloys.

As used herein, the term “thermal energy storage” (TES) refers to the process of storing heat or cold for later use. A medium (in this present disclosure PCM) may store heat (or cold) that can then be used to heat (or cool) water (or air) at a later time (typically storing/charging during on peak times and releasing/discharging during off peak times).

As used herein the term “off peak” refers to time (in minutes, hours, or days) not of the maximum energy use for a given energy user, grid, energy source, and/or electrical utility. A local electrical utility may define a certain time of day as “off peak” Generally, the cost of electrical energy during this time is reduced from the standard rate.

As used herein the term “on peak” refers to a time (in minutes, hours, or days) of the maximum energy use for a given energy user, grid, energy source, and/or electrical utility. A local electrical utility may define a certain time of day as “on peak.” Generally, the cost of electrical energy during this time is either the standard rate or elevated from the standard rate.

Among other things, the present disclosure relates to a heat pump hot water heater (HPWH) integrated with a PCM TES system for improving energy efficiency and/or allowing for a smaller space profile for the hot water heater. The PCM may provide TES capabilities to the hot water heater, allowing for load shifting, greater energy efficiency, and/or more water heating with a smaller space footprint. The PCM may allow for hot water to be provided without use of electrical energy and/or for a greater volume of hot water to be provided than the volume of the HPWH tank itself.

A HPWH may be any device or combination of devices for heating potable water which use electricity to move heat from one fluid to another (typically from a refrigerant to the water). A HPWH may also be referred to as a hybrid electric water heater. A HPWH may include resistive heating elements as well, although typically the primary mechanism for heating the water is via condenser coils containing the refrigerant. In many instances the condenser coils may be wrapped around the interior of the hot water tank and/or submerged in the water within the tank.

In some embodiments, the HPWH may utilize a PCM composite heat exchanger to increase heat transfer rates and “smart” controls to predict water use and demand. The HPWH with PCM composite heat exchanger as described herein may have several benefits over both traditional gas and electric hot water heaters and traditional HPWHs, including easier installation (less than approximately 2 hours), a uniform energy factor (UEF) higher than approximately 3.5 with a substantially similar (or higher) first hour rate (FHR) than conventional electric water heaters and provide demand flexibility using integrated PCM storage.

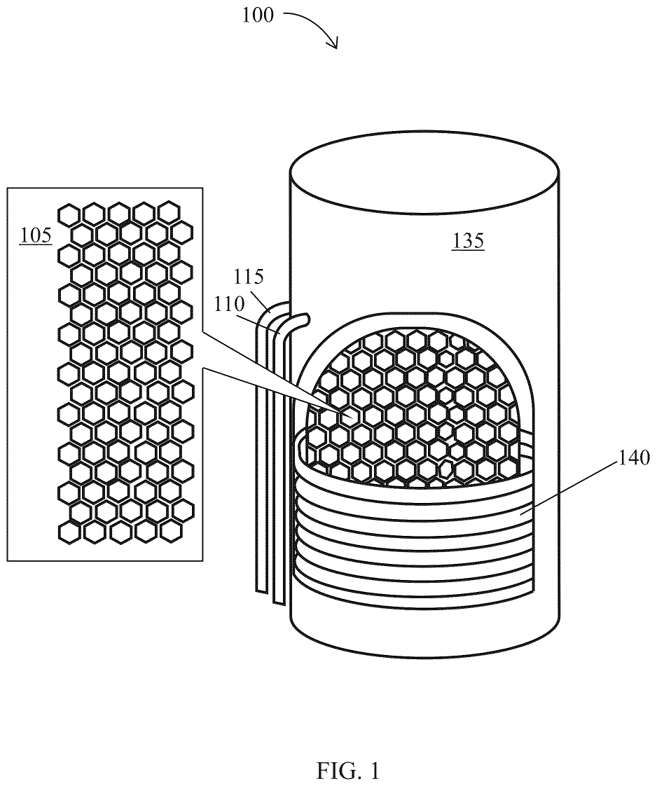

FIG. 1 illustrates a first embodiment of a HPWH 100 including a phase change material PCM 105, according to some aspects of the present disclosure. This embodiment of the HPWH 100 including a PCM 105 includes a 3D-printed microencapsulated PCM (MEPCM) scaffold along the walls of the tank interior 135. In the example shown in FIG. 1, the MEPCM manifold (i.e., the PCM 105 composite heat exchanger) is substantially in a honeycomb design, but other shapes, designs, and/or orientations could be used. The condenser coils 140 of the heat pump (not shown in FIG. 1) are in thermal communication with the PCM 105 and the water stored in the tank interior 135. As the condenser coils 140 heat the water in the tank interior 135, they also heat (i.e., charge) the PCM 105. This way the PCM 105 may be used to heat water in the tank interior 135 when the heat pump is “off” and/or when the condenser coils 140 would take too long to heat the water needed.

In some embodiments, PCMs 105 included with a HPWH 100 may enable storing energy more densely than water at lower temperatures (approximately 130° F. rather than approximately 140° F. as with typical HPWHs). This may require less volume (i.e., requires less space and may be capable of being stored in smaller spaces). This also may eliminate the need for a 3-way valve and improve the coefficient of performance (COP) of the HPWH 100 integrated with PCM 105 due to the smaller temperature lift. Thus, storage space lost to accommodate the heat pump (not shown in FIG. 1) may be mitigated by the additional latent heat storage capacity provided by the PCM 105. A problem with typical HPWHs is their inability to deliver enough hot water without back-up resistance heaters due to their lower first hour rating (FHR). In some embodiments, the HPWH 100 integrated with PCM 105 as described herein may integrate at least one PCM 105 and utilize a processor (not shown in FIG. 1) performing model predictive control (MPC) to ensure that the HPWH 100 integrated with PCM 105 can be utilized to meet the hot water demand. Also, in some embodiments, the condenser coils 140 in the HPWH 100 integrated with PCM 105 may utilize a 513A refrigerant with a global warming potential of approximately 573.

Over the course of a day, there is typically ample time to charge the HPWH 100 integrated with PCM 105 (approximately 10-20 hours). However, for PCMs 105 to provide significant value, they need to be able to discharge their stored thermal energy over a very short time (i.e., much less than about an hour) when there is a water draw on the tank 135. A common problem is that as the PCM 105 solidifies near the heat transfer surface during a water draw, its thermal resistance increases, effectively “shutting off” further transfer of heat. Solving this problem requires increased surface area, which adds cost and complexity. To rectify this, the PCM 105 may be in a composite of a thermoplastic polymer and microencapsulated PCM (MEPCM) as shown in FIG. 1 to attempt to maximize surface area. This means that the problem of thermal resistance may be addressed by integrating innovative additive manufacturing combined with fluid mechanics and heat transfer analysis to understand how increasing PCM 105 surface area and roughness, thermal conductivity, shape and/or thickness of encapsulation can achieve higher energy discharge rates and smart predictive controls to anticipate hot water needs based on previous water use.

PCMs 105 can store more energy per volume via latent heat as a result of phase change (e.g., transitioning from solid-liquid, approximately 140-230 kJ/kg) than the sensible heat required to raise water temperature from approximately 60° F. to approximately 120° F. (approximately 140 kJ/kg). Thus, even neglecting the sensible heat stored in the PCM 105, replacing water volume with PCM 105 will increase the energy storage capability, and provide additional flexibility in the use of the heat pump to charge the PCM 105 at off peak times of the day. As a user draws hot water from the tank 135, the previously heated water is replaced by cold water, reducing the temperature of the water. The melted (charged) PCM 105 then starts to deliver its stored latent heat to the water when the temperature of the water in the tank 135 drops below the transition temperature of the PCM 105. With proper thermal design the MEPCM shape, this energy transfer is fast enough to avoid the tank 135 running out of hot water and avoid energizing the electric elements (i.e., turning the heat pump “on”). The higher surface area and roughness of the MEPCM technology encourages turbulent flow to increase heat transfer between the PCM 105 and water in the tank 135 and provide this fast discharge. In some embodiments, a processor (not shown) using smart controls may predict water draws and PCM 105 thermal behavior and activate the HPWH 100 integrated with PCM 105 ahead of large water draws, which may improve customer satisfaction, improve coefficient of performance (COP), and reduce electric energy use when required by the electric utility or during on peak times.

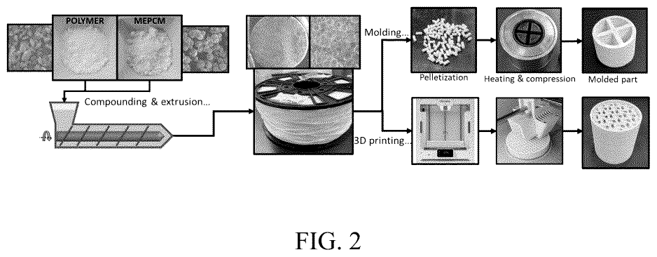

In some embodiments, as shown in FIG. 1, the PCM 105 may be submerged in the water in the tank interior 135 of the HPWH 100 integrated with PCM 105. The PCM 105 may include an MEPCM. Due to the double containment of the PCM 105 within the MEPCM, first in the core-shell microcapsules, and second being microcapsule containment within the polymer matrix, the PCM 105 composite may be substantially form-stable and substantially leak-proof. This is important for protecting the potable water in the tank 135 from contamination by the PCM 105 In some embodiments, the PCM 105 may have a melting temperature in the range of approximately 50-55° C. (i.e., approximately 122-131° C.). Some potential PCM/polymer matrix designs are shown in FIG. 2.

As shown in FIG. 2, the MEPCM may be created by combining a polymer and PCM 105, this combination may be extruded via 3D printing or molded into the desired shape. As shown in FIG. 1, an exemplary shape of the MEPCM may be a honeycomb structure. However, cylindrical, rectangular, triangular, planar, or other shapes may be used. The MEPCM may serve to contain the PCM 105 to prevent leaking into the water and to increase the surface area of the PCM 105 in thermal communication with the water.

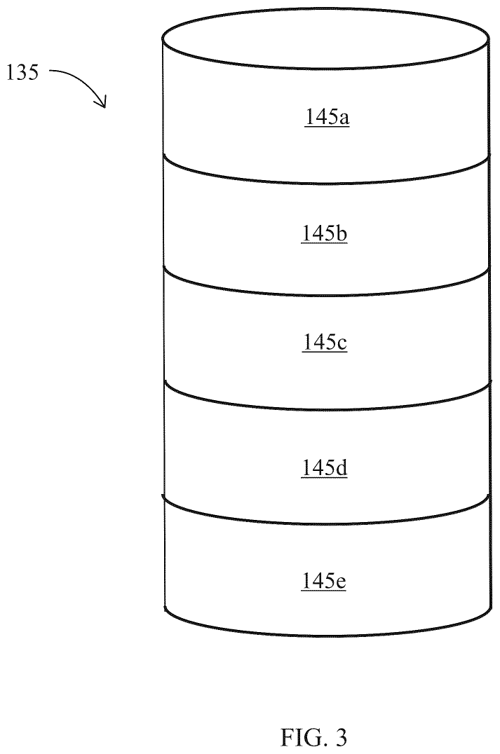

In some embodiments, the MEPCM/polymer scaffold may have a substantially high surface area and may be manufactured using 3D-printing. The use of 3D printing allows for manufacturing of high-surface area geometries such as a triply periodic minimal surface (TPMS) as shown in the bottom right of FIG. 2. With a substantially high surface area geometry such as TPMS may allow for greater heat transfer surface area in contact with eh water in the tank, enabling enhanced PCM charging and discharging. The unit cell size and surface wall thickness of the TPMS geometry are two parameters that can be varied independently to maximize heat transfer surface area to volume ratio. 3D-printing will also allow for better distribution of PCM 105 throughout the tank 135. For example, PCM 105 distribution may be concentrated toward the top of the tank 135, which will be at higher temperature when the tank 135 is stratified (as shown in FIG. 3), and/or near a backup resistance heat element if one is included. This may be achieved with 3D-printing by having higher TPMS cell density in the region requiring higher PCM 105 concentration.

In some embodiments, a substantially moderate surface area MEPCM/polymer scaffold may be manufactured using molding (as shown in the top right of FIG. 2). This may mitigate the potential risks of mass-manufacturing via 3D printing. This approach may limit the achievable surface area compared to 3D printing but being limited to rectilinear geometries with a substantially 2D profile that is substantially constant in the vertical direction, since the geometry much be realizable using a mold. Such geometries may have substantially moderate surface area (lower than 3D-printed TPMS); however, this approach may allow molding the PCM 105, using the same starting materials as with the 3D-printing approach. The physical metrics of the design options shown in FIG. 2 are summarized in Table 1. The data in Table 1 assumes a PCM 105 infill of approximately 35% of water in the tank 135 of the HPWH 100 integrated with PCM 105.

TABLE 1
Design comparison assuming PCM 105 infill
of approximately 35% of water tank 135

| | Option 1 (3D-printed | Option 2 (molded |
|---|---|---|
| | scaffold, TPMS geometry) | scaffold) |
| Surface Area (m²) | 16.9 | 6.4 |
| PCM volume (gallons) | 9.8 | 9.8 |
| Amount of PCM (kg) | 40 | 40 |
| Area/Volume ratio (1/m) | 500 | 200 |

Table 2 shows two potential MEPCM options (A & B) in the temperature range of interest for a HPWH 100 integrated with PCM 105 as described herein. In some embodiments, these may be bio-based, FDA approved PCMs 105, which are commercially available. There are ongoing R&D efforts focused on microencapsulation of inorganic salt-hydrate PCMs. In some embodiments, the present disclosure may allow for integration of salt-hydrate-based MEPCMs when available. Option C in Table 2 shows Sodium Acetate Trihydrate (SAT) which is one option for a salt-hydrate PCM 105 that may be used in the HPWH 100 integrated with PCM 105. Design of the MEPCM/polymer scaffold heat exchanger may be guided by numerical modeling. If needed, additional heat transfer enhancement such as incorporating thermally conductive fillers (e.g., carbonaceous or ceramic particles) into the matrix containing the PCM 105 may be included.

TABLE 2
Comparison of proposed PCMs 105

| | A | B | C |
|---|---|---|---|
| PCM type | Organic: | Organic: | Inorganic: Sodium |
| | Microtek | Encapsys | Acetate Trihydrate |
| | | | (SAT) |
| Latent heat (kJ/kg) | 200-210 | 190-200 | 220-240 |
| Melting range (° C.) | 52-54 | 52-54 | 57-59 |
| Thermal conductivity | 0.25-0.30 | 0.25 | 0.67 |
| (W/mK) | | | |
| Cost ($/kg) | 7-12 | 10-12 | 0.5-5 |
| Sensible heat capacity | 2.4-2.6 | 2.4-2.6 | 2.9 |
| (kJ/kgK) | | | |
| Density (kg/m³) | 840-920 | 750-800 | 1450 |

FIG. 2 shows an exemplary 3D scaffold developed using a thermoplastic polyurethane (TPU) polymer, which, in some embodiments, is not suitable for the HPWH 100 integrated with PCM 105 due to instability in aqueous environments at elevated temperatures. Suitable polymers may be stable in aqueous environments at elevated temperatures, and may be flexible, allowing high packing density of MEPCM. A preliminary shortlist of such polymers includes polyphenyl sulfone (PPSU), polypropylene (PP), polyvinylidene fluoride (PVDF), and acrylonitrile-styrene-acrylate (ASA).

An energy modeling tool for the HPWH 100 integrated with PCM 105 may solve the following mass and energy balances:

$${C}_{p}^{*} ρ Δ z \frac{{T}_{i}^{j + 1} - {T}_{i}^{j}}{Δ t} = {q}_{ambient} + {q}_{net} \qquad ( 1 )$$

$${q}_{ambient} = {UA}_{tank} ( {T}_{tank} - {T}_{ambient} ) \qquad ( 2 )$$

where q_{ambient} represents thermal losses to the environment and qₙₑₜ is the net energy transferred after considering: (1) water inlet/outlet transfer, (2) vertical heat transfer due to fluid flow from the node 145 above and below, (3) heat added by the heating element(s) and (4) mixing and conduction between nodes 145. These equations are discretized and solved for each node 145 using a finite difference algorithm to include all heat transfer between nodes 145 (see FIG. 3). A modeling challenge with PCMs 105 is how to incorporate them, and the models used may include using PCMs 105: varying Cp* to accommodate for the weighted average thermal storage (latent and sensible) and thermal conductivity of the nodes where the PCM 105 will be located. The HPWH 100 integrated with PCM 105 model may be calibrated using laboratory data for at least two PCM 105 configurations to ensure that it can accurately simulate the most promising designs. This is important to test since different shapes may increase turbulence inside the water heater and increase convective heat transfer. Validation tests may use realistic draw profiles and compare water temperatures throughout the tank 135 (i.e., the nodes 145) and electric input.

In a conventional HPWH, the control system regulates the water temperature using the different heating elements, depending on the deviation from the desired setpoint in the different tank zones/nodes. Generally, the heat pump turns on first and the backup elements are only triggered if the tank temperature continues to drop while the heat pump is running. The HPWH 100 integrated with PCM 105 with latent heat storage requires more complex control than a traditional HPWH for several reasons. First, the amount of energy stored is no longer proportional to the water temperature, as it will depend on the state of the PCM 105. This means that the “state of charge” of the HPWH 100 should be monitored using a model-based method. In order to charge the PCM 105 quickly, the water temperature in the tank 135 must rise significantly above the melting point of the PCM 105, but once the PCM 105 is fully charged, the water temperature in the tank 135 can drop to reduce standby losses. A control that applies power based on a simple temperature setpoint will likely not be sufficient in this case. Finally, to provide demand response the HPWH 100 state of charge must be managed to ensure enough heat is stored in the tank 135 to be able to coast through shed periods. This charging must occur before the demand response event. The phase change model may calculate the state-of-charge during the PCM 105 change of phase (when the temperature is constant).

The control system, which may be run by a processor (not shown) plays a critical role in achieving the quality-of-service goals of the HPWH 100 incorporating a PCM 105 of the present disclosure. In the case of a moderate hot water demand, an approximate 100% demand response can occur by charging ahead of time and delaying re-charge so that the power draw (i.e., PCM charging) occurs after the demand reduction event (i.e., a water draw on the tank 135). However, if the hot water draw is large, and additional hot water demands are expected, some additional electrical heating may be required to satisfy occupants.

The inclusion of PCMs 105 makes the control design more challenging, as it makes the relationship between thermal energy stored and internal tank 135 temperature substantially nonlinear. Thus, the advanced control system proposed herein includes several components that are beyond the current state of the art for HPWHs. A central theme may be model-based control design and implementation, where the term “model-based” includes both a model for the thermal-dynamic response of the water header and a probabilistic model for the hot water usage for the specific household location. Estimation of water flows and internal energy will be achieved using a model-based estimator, where temperature measurements and actuation commands are combined with a physics-based thermal model of the water tank to provide estimates of internal system parameters.

Once flows can be estimated, this information can be used to learn a probabilistic model for hot water usage. By combining knowledge of the distribution of expected hot water flows, the internal energy state within the HPWH 100 integrated with PCM 105, and a dynamic model of the thermal behavior of the HPWH with PCM heat exchanger, the control system can optimally manage the water heater in response to demand reduction requests. This will include calculating key information necessary for managing demand response. Over the demand response window, the controller calculates the expected peak power and energy usage, and the achievable upper and lower limits for deviating from the nominal peak power and energy (if requested by a demand response signal). Since the hot water draws are stochastic, these values are provided with probabilistic.

Depending on the amount and/or volume of PCMs 105 in the tank 135, the HPWH 100 integrated with PCM 105 may store the same (with about 35% PCM 105 by volume) or approximately 50% more thermal energy (with about 55% PCM 105 by volume) than a traditional 40-Gallon electric water heater tank (2.44 kWhₜ) while having a tank 135 approximately 30% smaller to allow for the heat pump with approximately 130° F. water (rather than approximately 140° F.) by adding PCMs 105.

While water heater rating systems use First Hour Rating (FHR) to compare different water heaters, this is not an ideal metric to verify demand response potential. Preliminary calculations using a domestic hot water profile generator to create draw profiles for a typical home in Sacramento in June show that the typical hot water use varies in the range of about 20-45 gallons from about 5-9 pm. Using a simplified, unsteady process over an open system (water tank), the tank energy balance is

$${U}_{cap , {final}^{-}} {U}_{cap , initial} = ( - {\dot{m}}_{tank} \cdot {h}_{out} + {Q}_{heater} ) \cdot time \qquad ( 3 )$$

$${Q}_{heater} = COP \cdot {Q}_{elec} \qquad ( 4 )$$

where Qₕₑₐₜₑᵣ stands for the delivered thermal energy to the HPWH 100, Q_{elec} is the compressor power, mₜₐₙₖ is the mass flow rate leaving the boiler, hₒᵤₜ is the enthalpy of the water leaving the water heater and the U's are the initial and final tank internal energy. To simplify calculations, it is assumed that water use is used substantially evenly distributed over approximately 4 hrs, substantially no heat input is required, substantially no losses, thermocline at final state is approximately half of the tank height, latent heat of approximately 200 kJ/kg, COP is approximately 3.5, and inlet water temperature is approximately 14.4° C. (mains water temperature from the UEF test, approximately 58° F.). Tank size is approximately 40 gallons for baseline electric water heater (EWH) and approximately 28 gallons for the HPWH 100 to allow for the HP to sit on top of the tank 135. Initial and final internal energy includes PCM 105 sensible and latent heat as well as water sensible heat and the water mass displaced by the PCMs 105. Initial temperature is kept approximately 130° F. (or approximately 54° C.) for the HPWH 100 integrated with PCM 105 and approximately 140° F. (or approximately 60° C.) for the baseline EWH.

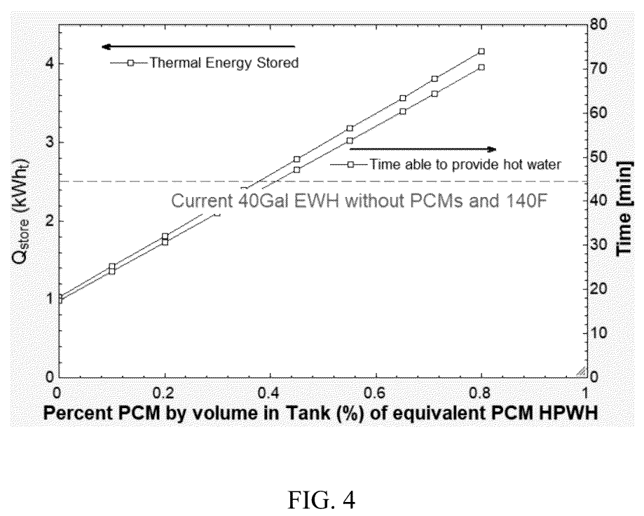

FIG. 4 shows results from this analysis. Left vertical axis shows HPWH 100 integrated with PCM 105 thermal capacity (Qₛₜₒᵣₑ) to provide hot water without any substantial heating input, left vertical axis shows time (in minutes) HPWH 100 integrated with PCM 105 can supply approximately 120° F. water. The horizontal axis shows the percentage of volume inside the tank 135 occupied by the PCMs 105. This preliminary analysis shows that the HPWH 100 integrated with PCM 105 having approximately 30-50% PCM 105 could outperform current EWH while reducing approximately 30% its tank 135 volume needed to house the heat pump on top of the top so the HPWH 100 integrated with PCM 105 can fit in a tight utility closet.

This energy analysis is simplified and needs to include time dependent effects such as specific draw profiles, relative losses of storing water at higher temperatures and temperature stratification effects within the tank 135. It is also important to analyze the FHR, with an approximately 3 gal/min flow rate. Table 3 compares a baseline water heater to the HPWH 100 integrated with PCM 105, under the assumption that the PCM 105 can release stored heat within about an hour.

TABLE 3
Comparison between baseline and proposed
water heater (Option B Table 2)

| | Existing 240 V EWH | Proposed equivalent |
|---|---|---|
| | (AO Smith does not | 40 Gal HPWH |
| | have a 40 Gal HPWH) | (expected) |
| Potential Thermal | 2.4 | 1.4-3.8 (10-70% |
| Storage (kWh) | | PCM by volume) |
| Rated Volume (Gallons) | 40 | 40 |
| Actual Water Volume | 45 | 28 |
| (Gallons) | | |
| Total Weight (kg) | 50 | 64 |
| PCMs (kg) | 0 | 12-82 kg (0-70% |
| | | PCM by volume) |
| First-hour rating (Gallons) | 44 | 20-75 |
| Recovery rate (GPH) | 31.8 | 11-40 |
| Expected Additional Cost | 0 | 320-1,300 |
| ($) | | |

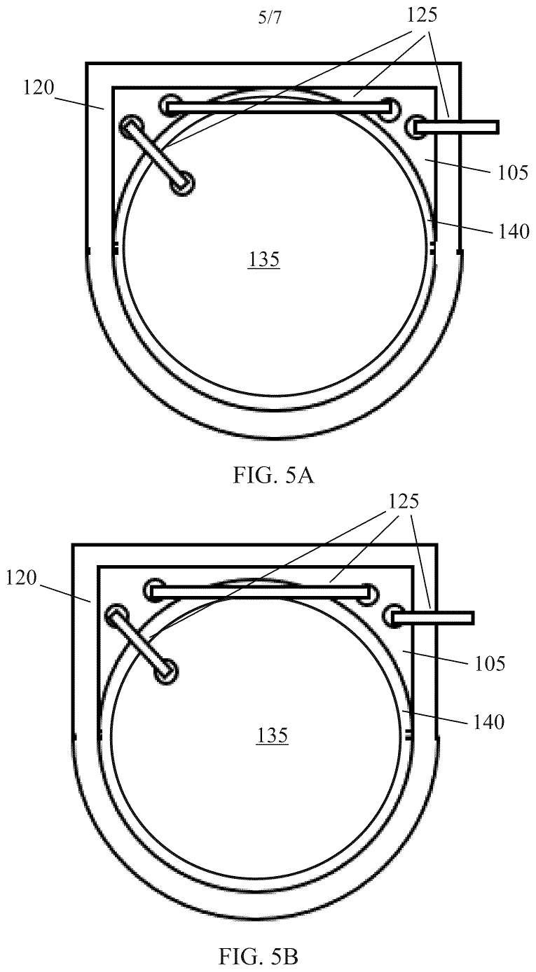

Another embodiment of the present disclosure invention adds additional TES (using PCM 105) to the HPWH 100, in the corners around the cylindrical heat pump water heater (See FIGS. 5A-B). This additional storage consists of a PCM 105 which releases heat upon freezing. This could be in one or more of the corners (PCM 105 in two corners are shown in FIG. 5). Water heater tanks are typically round because they must withstand pressures above about 100 psi, and square pressure vessels are prone to failure. But the closet or other storage spaces these tanks fit into are often square, rectangular, and/or have unused corners. This means the extra space taken by the PCM 105 in the corners of the storage space is acceptable in most installation scenarios.

FIG. 5A illustrates a top view of a second embodiment of a PCM-integrated HPWH having PCM integrated in two external corners; FIG. 5B illustrates a top view of a second embodiment of a PCM-integrated HPWH having PCM integrated into two external corners and a single side, according to some aspects of the present disclosure. Each embodiment shows how the PCM 105 can use storage space and not tank 135 space.

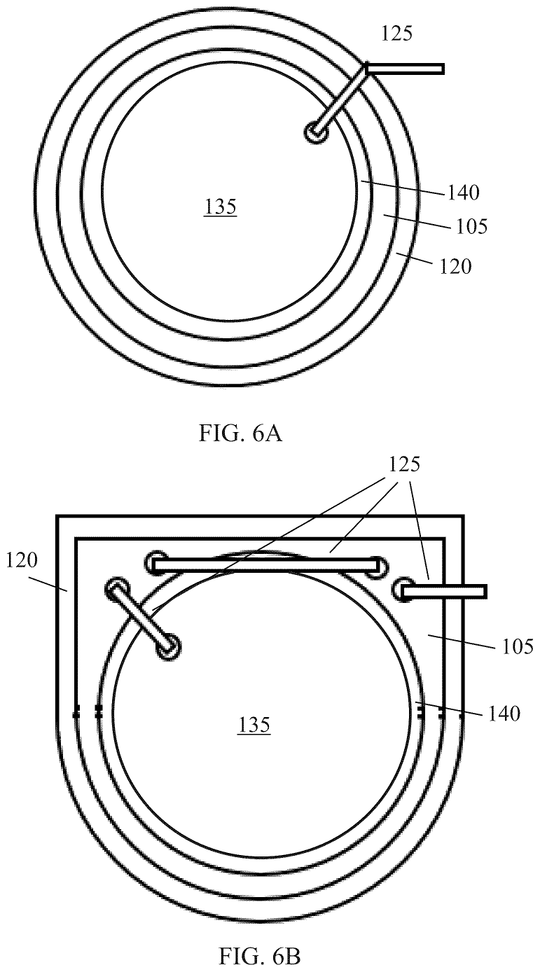

FIG. 6A illustrates a top view of a second embodiment of a PCM-integrated HPWH having PCM surrounding the water tank; FIG. 6B illustrates a top view of a second embodiment of a PCM-integrated HPWH having PCM surrounding the water tank and integrated into two external corners and a side, according to some aspects of the present disclosure. The embodiment shown in FIG. 6A shows

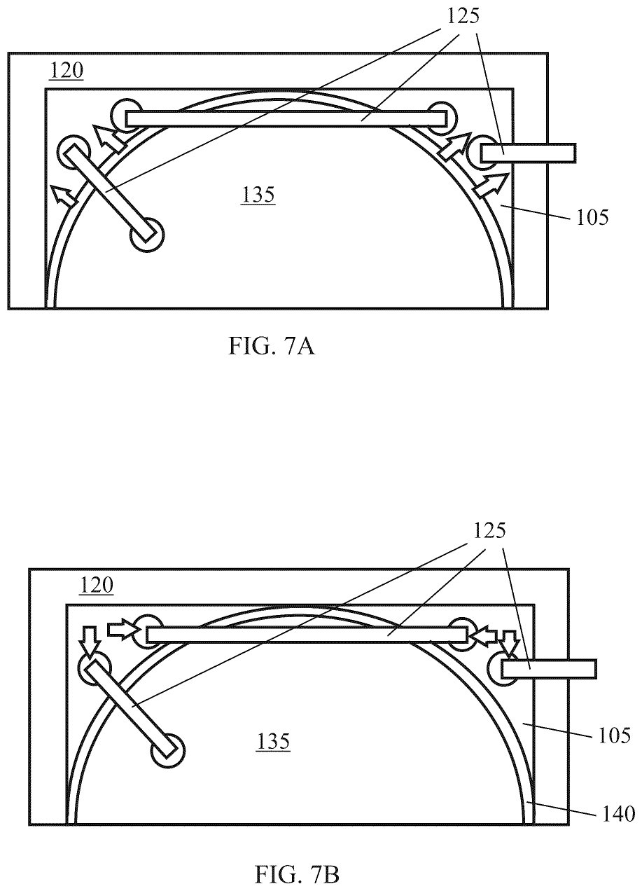

FIG. 7A illustrates a close up top view of a second embodiment of a PCM-integrated heat pump water heater during charging and FIG. 7B illustrates a second embodiment of a close up top view of a PCM-integrated heat pump water heater during discharging, according to some aspects of the present disclosure.

In some embodiments, as the hot water in the tank 135 is depleted and the temperature of the water in the tank 135 decreases below the transition temperature of the PCM 105, the PCM 105 will freeze, and heat the water before the water goes to the end user (e.g., shower, sink, appliance, etc.). The pipe (made of copper or another conductive metal) exiting the tank 135 will traverse down and back up through the PCM 105, as shown in FIGS. 5A-B, 6A-B, and 7A-B. This could be one down-and-up pass per PCM 105 corner, as shown, or more.

In some embodiments, the PCM 105 can be charged in one of two ways. One option is to rely on the hot water in the pipe 125, already existing the tank 135, while the water in the tank 135 is still hot. This hot water would be above the PCM 105 transition temperature, so that it melts the PCM 105 as it passes through it (i.e., charges the PCM 105). The timing of this method is important, because it will need to be a period when the users are requesting hot water, but also must not be a continuous withdraw of heat, or there is no benefit of the additional storage (i.e., if the energy from the hot water heats the PCM 105, which later heats the hot water-no net benefit).

In some embodiment, the other charging option is to rely on the condenser coils 140, which typically wrap around the HPWH 100 (as described above). This is shown in FIGS. 7A-B. FIG. 7A shows the charging process, where the hot condenser coils 140 heat both the water in the tank 135, and the PCM 105 wrapped around the tank 135 and/or the coils 140. This melts the PCM 140 (i.e., charges the PCM 105). FIG. 7B shows the discharging process. This process starts once the water temperature exiting the tank 135 (and flowing through the pipes 125) drops below the PCM 105 transition temperature. The PCM 105 should be selected so that the transition temperature is just below the typical outlet temperature of the tank 135.

In some embodiments, heat transfer into the PCM 105 from the condenser coils 140, and from the PCM 105 into the conductive pipes 125 is limited by conduction, and potentially natural convection, inside the PCM 105. This may be too slow using traditional, pure PCMs 105. Thus, the PCM 105 may be a composite PCM 105 with high thermal conductivity. One embodiment may include a phase change composite from a PCM 105 soaked into a porous graphite matrix. In some embodiments, this may be substantially similar to the 3D-printed microencapsulated PCM (MEPCM) scaffold shown in FIG. 1. Other embodiments may include fillers inside the PCM 105 (e.g., a mesh or foam), and/or aluminum fins around the copper pipes 125 that are routed through the PCM 105. In some embodiments, the PCM 105 may be a salt hydrate (identified by the formula MₚX_{q}·nH₂O). Exemplary PCMs 105 may have a transition temperature near the set temperature of the HPWH 100 (typically approximately 37° C. to approximately 60° C.). Most HPWHs 100 are set to a target temperature of approximately 40° C. This means exemplary PCMs 105 will have a transition temperature in the range of approximately 35° C. to approximately 65° C.

FIGS. 5A-B illustrates a top view of a heat pump water heater with PCM 105-integrated in two of the corners in the storage space of the tank 135. In the embodiments shown in FIGS. 5A-B, a pipe (often the outlet of water from the tank, although it could be the inlet) flows down and up through the PCM 105 twice, but in other embodiments the pipe could contact the PCM 105 more. More contact with the PCM 105 may result in greater heat transfer between the PCM 105 and the pipes 125. If the PCM 105 is integrated into additional sides (as in FIG. 5B) and/or corners (not shown) or surrounding the entire tank 135 (as in FIGS. 6A-B), the number of times the pipes 125 contact the PCM 105 may be increased. When the pipes 125 are taking heated water from the tank 135 to an end use, the PCM 105 may provide heat to the water when the volume of water drawn by the end user has exceeded that of the tank 135. That is, when the water draw results in the water in the tank 135 and/or pipes 125 being less than the transition temperature of the PCM 105, the PCM 105 may provide heat to the water. This may increase the volume of water provided to the end user without the use of additional electrical energy.

An alternative embodiment uses a similar design as shown in FIGS. 5A, 5B, 6A, and 6B, except that the tubes exchanging heat with the PCM 105 are the inlet pipes 125 to the tank, rather than the outlet pipes 125. This will preheat the water entering the tank 135, rather than heating the water exiting the tank 135 to the desired setpoint temperature. The PCM 105 would still be charged with the condenser coils 140, as shown in FIG. 7A.

FIGS. 7A-B illustrates a close-up top-view drawing of water tank 135 and integrated PCM 105 storage. FIG. 7A shows charging process, where the hot condenser coils 140 heat both the water in the tank 135 and the PCM 105 surrounding the tank 135 when the heat pump (not shown) is operating to heat the HPWH 100. This melts the PCM 105, storing thermal energy in the PCM 105. FIG. 7B shows the discharging process. The discharging process starts once the temperature of the water exiting (or entering, fit eh pipes 125 are inlet pipes) the tank 105 drops below the PCM 105 transition temperature and heat is transferred from the PCM 105 to the water in the tank 135 and/or pipes 125.

### Examples

Example 1. A method comprising:
charging a phase change material using a condenser coil;
heating a water using the condenser coil;
storing the water in a tank; and
discharging the phase change material using the water; wherein:
the condenser coil is a part of a heat pump water heater,
the phase change material has a transition temperature,
the charging occurs when the condenser coil is at a temperature higher than the transition temperature, and
the discharging occurs when the water is at a temperature less than the transition temperature.

Example 2. The method of Example 1, wherein:
the charging comprises:
transferring a heat from the condenser coil to the phase change material; wherein:
the charging results in the phase change material being in a substantially liquid state.

Example 3. The method of Example 1, wherein:
the heating comprises operating the heat pump hot water heater.

Example 4. The method of Example 1, wherein:
the phase change material is located inside the tank.

Example 5. The method of Example 4, wherein:
the charging comprises transferring heat from the condenser coil to the water, and
the water heats the phase change material when the water is at a temperature greater than the transition temperature.

Example 6. The method of Example 4, wherein:
the phase change material comprises at least one of polyphenyl sulfone (PPSU), polypropylene (PP), polyvinylidene fluoride (PVD), or acrylonitrile-styrene-acrylate (ASA).

Example 7. The method of Example 4, wherein:
the discharging comprises:
transferring a heat from the phase change material to the water, resulting in the water increasing in temperature.

Example 8. The method of Example 1, wherein:
the phase change material is located outside of the tank.

Example 9. The method of Example 8, wherein:
the phase change material comprises a salt hydrate.

Example 10. The method of Example 8, wherein:
a piping is configured to direct the water from the tank to an end use, and
the piping is positioned within the phase change material.

Example 11. The method of Example 10, wherein:
the discharging occurs when the water in the piping is at a temperature less than the transition temperature.

Example 12. The method of Example 8, wherein:
a piping is configured to direct the water to the tank, and
the piping is positioned within the phase change material.

Example 13. The method of Example 12, wherein:
the discharging occurs prior to the heating.

Example 14. The method of Example 13, wherein:
the discharging occurs when the water in the piping is at a temperature less than the transition temperature.

Example 15. The method of Example 1, wherein:
the transition temperature is approximately 40° C.

Example 16. A device comprising:
a heat pump comprising a condenser coil;
a tank comprising an interior; and
a phase change material in thermal communication with the condenser coil and having a transition temperature; wherein:
the condenser coil is configured to heat a water,
the condenser coil is configured to heat the phase change material when the phase change material is at a temperature less than the transition temperature, and
the phase change material is configured to heat the water when the water is at a temperature less than the transition temperature.

Example 17. The device of Example 16, wherein:
the tank is configured to store the water in the interior.

Example 18. The device of Example 16, wherein:
the phase change material is located in the interior.

Example 19. The device of Example 18, wherein:
the phase change material is contained in a matrix.

Example 20. The device of Example 18, wherein:
the phase change material comprises at least one of polyphenyl sulfone (PPSU), polypropylene (PP), polyvinylidene fluoride (PVD), or acrylonitrile-styrene-acrylate (ASA).

Example 21. The device of Example 18, wherein:
the phase change material is configured to heat the water when the water in the interior is at a temperature less than the transition temperature.

Example 22. The device of Example 16, wherein:
the phase change material is located outside of the tank.

Example 23. The device of Example 22, wherein:
the phase change material comprises a salt hydrate.

Example 24. The device of Example 23, wherein:
a piping is configured to direct the water from the tank to the end use, and
the piping is positioned within the phase change material.

Example 25. The device of Example 24, wherein:
the phase change material is configured to heat the water when the water in the piping is at a temperature less than the transition temperature.

Example 26. The device of Example 23, wherein:
a piping is configured to direct the water to the tank, and
the piping is positioned within the phase change material.

Example 27. The device of Example 26, wherein:
the phase change material is configured to transfer heat to the water before the water enters the interior, and
the phase change material is configured to heat the water when the water when the water in the piping is at a temperature less than the transition temperature.

Example 28. The device of Example 16, wherein:
the condenser coil comprises a refrigerant.

Example 29. The device of Example 28, wherein:
the refrigerant comprises a R513A refrigerant.

Example 30. The device of Example 16, wherein:
the transition temperature is approximately 40° C.

The foregoing discussion and examples have been presented for purposes of illustration and description. The foregoing is not intended to limit the aspects, embodiments, or configurations to the form or forms disclosed herein. In the foregoing Detailed Description for example, various features of the aspects, embodiments, or configurations are grouped together in one or more embodiments, configurations, or aspects for the purpose of streamlining the disclosure. The features of the aspects, embodiments, or configurations may be combined in alternate aspects, embodiments, or configurations other than those discussed above. This method of disclosure is not to be interpreted as reflecting an intention that the aspects, embodiments, or configurations require more features than are expressly recited in each claim. Rather, as the following claims reflect, inventive aspects lie in less than all features of a single foregoing disclosed embodiment, configuration, or aspect. While certain aspects of conventional technology have been discussed to facilitate disclosure of some embodiments of the present invention, the Applicants in no way disclaim these technical aspects, and it is contemplated that the claimed invention may encompass one or more of the conventional technical aspects discussed herein. Thus, the following claims are hereby incorporated into this Detailed Description, with each claim standing on its own as a separate aspect, embodiment, or configuration.

What is claimed is:

1. A method comprising:
charging a phase change material using a condenser coil;
heating a water using the condenser coil;
storing the water in a tank; and
discharging the phase change material using the water; wherein:
the condenser coil is a part of a heat pump water heater,
the phase change material has a transition temperature,
the charging occurs when the condenser coil is at a temperature higher than the transition temperature, and
the discharging occurs when the water is at a temperature less than the transition temperature.

2. The method of claim 1, wherein:
the heating comprises operating the heat pump hot water heater.

3. The method of claim 1, wherein:
the transition temperature is approximately 40° C.

4. The method of claim 1, wherein:
the phase change material is located inside the tank,
the charging comprises transferring heat from the condenser coil to the water, and
the water is configured to heat the phase change material when the water is at a temperature greater than the transition temperature.

5. The method of claim 4, wherein:
the discharging comprises:
transferring a heat from the phase change material to the water, resulting in the water increasing in temperature.

6. The method of claim 1, wherein:
the phase change material is located outside of the tank,
a piping is configured to direct the water from the tank to an end use, and
the piping is positioned within the phase change material.

7. The method of claim 6, wherein:
the discharging occurs when the water in the piping is at a temperature less than the transition temperature.

8. The method of claim 1, wherein:
the phase change material is located outside of the tank,
a piping is configured to direct the water to the tank, and
the piping is positioned within the phase change material.

9. The method of claim 8, wherein:
the discharging occurs prior to the heating.

10. The method of claim 8, wherein:
the discharging occurs when the water in the piping is at a temperature less than the transition temperature.

11. A device comprising:
a heat pump comprising a condenser coil;
a tank comprising an interior; and
a phase change material in thermal communication with the condenser coil and having a transition temperature; wherein:
the condenser coil is configured to heat a water,
the condenser coil is configured to heat the phase change material when the phase change material is at a temperature less than the transition temperature, and
the phase change material is configured to heat the water when the water is at a temperature less than the transition temperature.

12. The device of claim 11, wherein:
the transition temperature is approximately 40° C.

13. The device of claim 11, wherein:
the phase change material is located in the interior,
the phase change material is contained in a matrix, and
the phase change material is configured to heat the water when the water in the interior is at a temperature less than the transition temperature.

14. The device of claim 13, wherein:
the phase change material comprises at least one of polyphenyl sulfone (PPSU), polypropylene (PP), polyvinylidene fluoride (PVD), or acrylonitrile-styrene-acrylate (ASA).

15. The device of claim 13, wherein:
the phase change material is configured to heat the water when the water in the interior is at a temperature less than the transition temperature.

16. The device of claim 11, wherein:
the phase change material is located outside of the tank, and
the phase change material comprises a salt hydrate.

17. The device of claim 11, wherein:
the phase change material is located outside of the tank,
a piping is configured to direct the water from the tank to the end use, and
the piping is positioned within the phase change material.

18. The device of claim 17, wherein:
the phase change material is configured to heat the water when the water in the piping is at a temperature less than the transition temperature.

19. The device of claim 11, wherein:
the phase change material is located outside of the tank, a piping is configured to direct the water to the tank, and
the piping is positioned within the phase change material.

20. The device of claim 19, wherein:
the phase change material is configured to transfer heat to the water before the water enters the interior, and
the phase change material is configured to heat the water when the water when the water in the piping is at a temperature less than the transition temperature.
